(19) United States
(12) Patent Application Publication
(10) Pub. No.: US 2015/0163912 A1
(43) Pub. Date: Jun. 11, 2015

(54) MOUNTING IN CIRCUIT BOARD

(71) Applicant: Corning MobileAccess Ltd., Airport City (IL)

(72) Inventors: Rami Reuven, Rishon Letzlon (IL); Yaakov Shaul, Kfar-Saba (IL)

(73) Assignee: Corning MobileAccess Ltd., Airport City (IL)

(21) Appl. No.: 14/097,868

(22) Filed: Dec. 5, 2013

(51) Int. Cl. H05K 1/14; H05K 3/30; H05K 3/32; H05K 1/18

(52) U.S. Cl. CPC H05K 1/144; H05K 1/181; H05K 3/303; H05K 3/32; H05K 2201/10174

(57) ABSTRACT

In a printed circuit board having stacked units, a protruding portion of a first of the units can extend across and past at least one of the peripheral edges of a non-conductive substrate of a second of the units. The protruding portion of the first unit may include at least a portion of a conductor of the first unit, and the portion of the conductor of the first unit may be configured for being connected to an electronic device. The electronic device may include conductive leads or legs protruding from a body of the electronic device so that a gap is defined between the legs, and the protruding portion of the first unit may be positioned in the gap. Circuit board conductors on opposite sides of the protruding portion may be respectively connected to the legs, such as by soldering.

### BACKGROUND

This disclosure relates generally to circuit boards and more particularly to printed circuit boards that may have one or more electronic devices, such as but not limited to a laser diode, mounted thereto.

It is known for the conductive legs of a laser diode to be bent in order to allow the legs to be soldered to respective conductors of a printed circuit board, wherein the laser diode is configured for transmitting optical signals through an optical fiber cable. The bending of the legs may be disadvantageous because, for example, it may involve complicated manual labor; it may cause stress in the enclosure of the laser diode, which may damage the laser diode, such as by causing cracking in the glass feed-through and/or otherwise reducing mean time between failures; and it may require the legs to be relatively long so that they can be soldered in the same plane, which may negatively impact radio frequency performance, such as bandwidth.

### SUMMARY

An embodiment of this disclosure relates to a printed circuit board having layers or units secured in a stack arrangement, wherein a protruding portion of a first of the units may extend across and past at least one of the peripheral edges of a non-conductive substrate of a second of the units, the protruding portion of the first unit may comprise at least a portion of a conductor of the first unit, and the conductor of the first unit may be configured for being connected to an electronic device.

In one aspect, the electronic device may include conductive leads or legs protruding from a body of the electronic device so that a gap is defined between the legs, and the protruding portion of the first unit may be positioned in the gap. Circuit board conductors on opposite sides of the protruding portion may be respectively connected to the legs, such as by soldering. A cut-out or cavity may be adjacent to the protruding portion so that the protruding portion has a reduced thickness as compared to another portion of the circuit board, and one or more of the legs may extend in to the cavity.

In one example, the electronic device preferably (e.g., optionally) is a laser diode that may be positioned in a hole of the circuit board, and substantially the entire length of the laser diode's legs may extend substantially straight. That is and in accordance with one example, the legs of the laser diode may remain substantially unbent and substantially unstretched throughout the mounting and use of the laser diode, which seeks to at least reduce one or more of the potential problems mentioned in the Background section of this disclosure. Alternatively, some stretching or bending of the legs may occur, if desired and depending upon the relative importance of a variety of factors that may be balanced. Notwithstanding, one aspect of this disclosure is the provision of one or more features that may be used in an effort to at least reduce the need for any stretching and/or bending of the legs.

In one example of a method of assembling, there may be relative movement between the laser diode and the circuit board, so that the respective conductors of the circuit board become positioned in the gap defined between the legs of the laser diode. As a more specific example, the laser diode may be moved in a first direction into the hole in the circuit board, and then the laser diode may be moved in a second direction so that the respective conductors of the circuit board become positioned in the gap defined between the legs of the laser diode. Then the legs may be connected to the respective conductors of the circuit board, such as by soldering.

The laser diode device may be more generally referred to as a light-emitting diode, or even more generally as an electronic device.

Additional features and advantages will be set forth in the detailed description which follows, and in part will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 is a pictorial view of a laser diode device, in accordance with an embodiment of this disclosure.

FIG. 2 is schematic pictorial view of a portion of a circuit board, in accordance with an embodiment.

FIG. 3 is a schematic top plan view of a portion of the circuit board of FIG. 2.

FIG. 4 is a schematic top plan view of the laser diode mounted to a portion of the circuit board, in accordance with an embodiment.

FIG. 5 is a schematic bottom plan view of a portion of the combination shown in FIG. 4.

FIG. 6 is a schematic cross-sectional view taken along line 6-6 of FIG. 4.

### DETAILED DESCRIPTION

Various embodiments will be further clarified by the following examples.

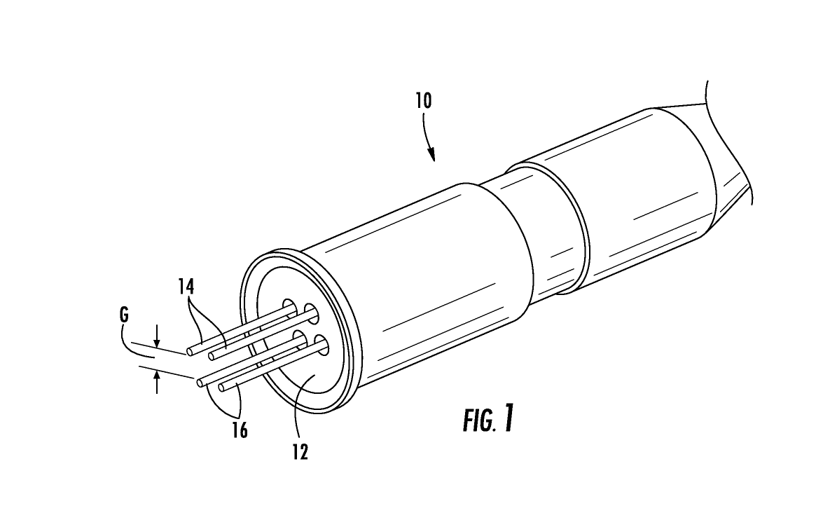

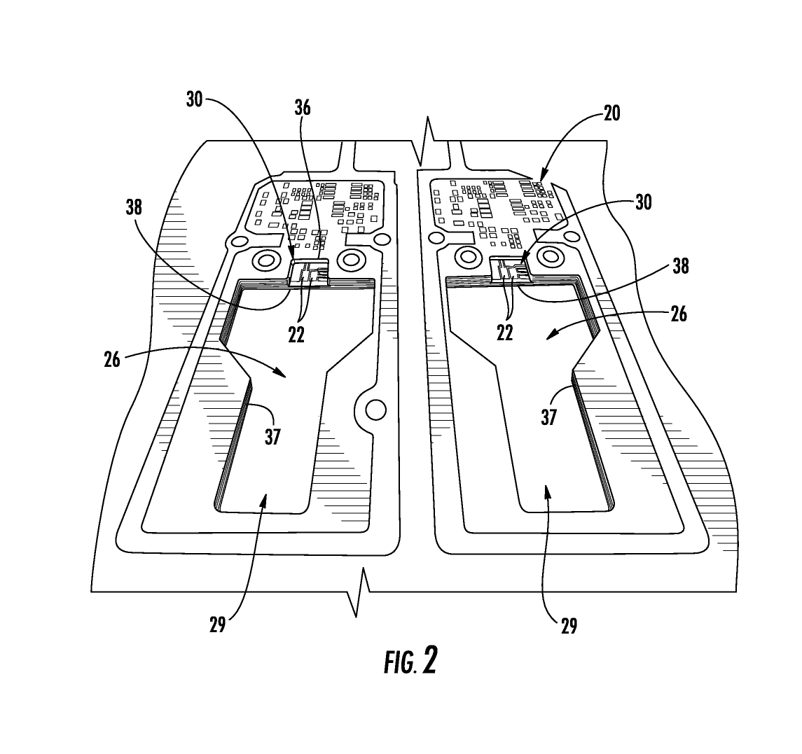

Referring to FIG. 1 and considered in isolation, a laser diode device 10 of an embodiment of this disclosure may be conventional. The laser diode device 10 includes a body having an enclosure, wherein the enclosure includes a disk-shaped base 12 through which elongate conductive contacts, leads or legs 14, 16 extend. There may be one or more upper legs 14 and one or more lower legs 16. In the embodiment illustrated in the drawings, there are two upper legs 14 and two lower legs 16. The pair of upper legs 14 may extend in a common upper plane and the pair of lower legs 16 may extend in a common lower plane, wherein a distance or gap G is defined between the upper and lower legs for receiving a peripheral portion of a printed circuit board 20 (FIGS. 2-6), as will be discussed in greater detail below.

In an embodiment of this disclosure, FIG. 1 represents an isolated view of the laser diode device 10 both prior to it being mounted to the printed circuit board 20 and after the laser diode device has been mounted to the printed circuit board. As shown in FIG. 1 for each conductive lead or leg 14, 16, the entire length of the leg that extends outwardly from the base 12 (e.g., the exposed portion of the leg) extends straight and perpendicular to the plane of the exterior surface of the base. In practice, it may not be practical for the entire length of the exposed portion of each leg 14, 16 to extend perfectly straight and perpendicular to the plane of the exterior surface of the base 12. Therefore, reasonable tolerances (e.g., dimensional and/or angular variations) are within the scope of this disclosure, such that for at least some of and preferably (e.g., optionally) all of the legs 14, 16, substantially the entire length of the exposed portion of the leg may extend substantially straight and substantially perpendicular to the plane of the exterior surface of the base 12.

When originally manufactured, the length of each of the legs 14, 16 of the laser diode 10 may be about 12.0 mm. Preferably (e.g., optionally), the ends of the legs 14, 16 are cut away to reduce the length of the legs 14, 16 to about 2.5 mm to about 3.0 mm, and more specifically it is these legs 14, 16 of reduced length that may extend substantially straight and/or substantially perpendicularly, and that are mounted to the circuit board as discussed in greater detail below. Shortening the legs 14, 16 seeks to improve electrical performance of the laser diode 10.

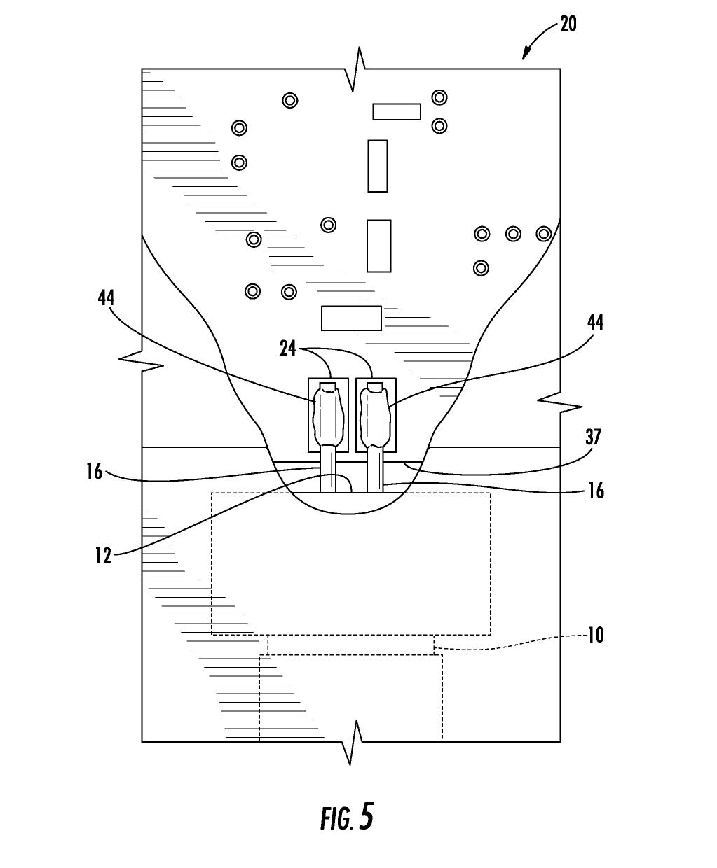

In one embodiment and as will be discussed in greater detail below, after the laser diode 10 has been mounted to the printed circuit board 20, such as by soldering the legs 14, 16 to respective conductors 22 (FIGS. 2-4) and 24 (FIG. 5) of the printed circuit board, for at least some of and preferably (e.g., optionally) all of the legs, substantially the entire length of the exposed portion of the leg extends substantially straight and/or substantially perpendicular to the plane of the exterior surface of the base 12, or the like. As an example and not for the purpose of limiting the scope of the present embodiments, these configurations of the legs 14, 16 seek to overcome at least some of the problems mentioned in the Background section of this disclosure. Notwithstanding the foregoing, variations in the configurations of the legs 14, 16 are within the scope of this disclosure. For example, the degree of straightness and/or perpendicularity may be varied in view of economic and/or other relevant factors.

FIG. 2 is an isolated pictorial view of a portion of the printed circuit board 20 to which two of the laser diode devices 10 may be mounted, wherein the lasers may be respectively positioned in through-holes 26 (e.g., cut-out) in the circuit board. It is within the scope of this disclosure for any suitable number of the lasers 10 to be mounted to a circuit board 20, and optionally more than one laser may be positioned in the same through-hole 26. Notwithstanding and for ease of discussion, and not for the purpose of limiting the scope of the present embodiments, a single laser 10 and a single hole (e.g., through-hole 26) are often referred to in this disclosure.

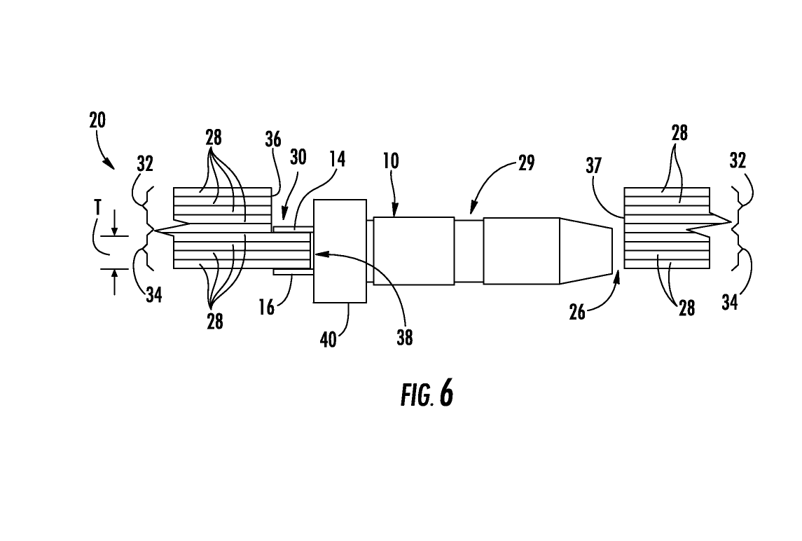

Some features of the printed circuit board 20, such as those not related to the mounting of the laser 10, may be conventional. For example, those of ordinary skill in the art will understand how to make a circuit board so that it includes units (e.g., layers) that are secured in a stacked arrangement by laminating and/or other suitable fastening techniques, wherein each unit typically includes a slab-shaped, non-conductive substrate having opposite top and bottom major sides that each include peripheral edges, and minor edges or sides respectively extending between the peripheral edges of the opposite major sides, and one or more conductors (e.g., conductive traces and/or conductive pads) mounted to one or both of the major sides. An example of a stacked arrangement of the units 28 of the circuit board 20 is shown in FIG. 6.

Those of ordinary skill will understand that forming a unit 28 typically includes laminating a conductive sheet to one of the major sides of a non-conductive substrate, or respectively laminating conductive sheets to both of the major sides of the non-conductive substrate. Then, a resist coating may be printed onto the exposed surface of each conductive sheet. Then, the portions of the conductive sheet that are not protected by the resist coating may be chemically etched away, so that the conductive traces are left intact. The non-conductive substrate may comprise glass fibers and epoxy resin, and the conductive sheets and conductive traces may be copper, although any other suitable materials may be used. Alternatively, the conductive traces may be formed in any other suitable manner such as, but not limited to, mechanical milling. Conductive traces and/or other features, such as copper conductive pads, of the circuit board 20 may be connected to one another by way of conductive material extending through (e.g., lining) holes in the non-conductive substrates. Conductive pads may be respectively mounted to the non-conductive substrates, and conductive pads may be respectively connected to the holes lined with conductive material in a conventional manner. Conventional electronic devices such as, but not limited to, capacitors and resistors, or the like, may be mounted to the circuit board 20 and connected to respective conductors of the circuit board. The conductors 22 (FIGS. 2-4) and 24 (FIG. 5) of the circuit board 20 may be conductive pads and/or conductive traces. In one embodiment (e.g., the embodiment illustrated in the drawings), the upper conductors 22 are conductive pads and the lower conductors 24 are conductive traces, although the conductors 22, 24 may be any other suitable features.

As shown in FIG. 2, the generally horizontally arranged circuit board 20 includes two compound holes 29, wherein each compound hole includes a through-hole 26 and cavity 30 (e.g., cut-out). Referring also to FIG. 6, the through-hole 26 is defined by both upper and lower portions 32, 34 of the circuit board 20, and the cavity 30 is generally defined by the upper portion, wherein the cavity is laterally open to the through-hole 26. Alternatively, the cavity 30 may be generally defined by the lower portion 34 (e.g., the circuit board 20 may be inverted). As other examples, the through-hole 26 may be configured differently so as to extend only partially through the circuit board 20, and the circuit board may be oriented in arrangements other than the generally horizontal arrangement shown in FIGS. 2 and 6, such as by being rotated so that the length of the circuit board extends vertically or in any other suitable configuration. As another alternative, at least a portion of, or all of, the upper portion 32 of the circuit board 20 may be omitted

Considering the circuit board 20 in the generally horizontal orientation shown in FIGS. 2 and 6, each of the upper and lower portions 32, 34 of the circuit board may include or be in the form of one or more layers or units 28 secured in a stack arrangement. The portions 32, 34 and units 28 may be substantially parallel to one another, respectively in opposing face-to-face contact with one another, and secured in the stacked arrangement by laminating and/or other suitable fastening techniques. Optionally, the outer peripheral edges of one or more of, or all of, the units 28 may be substantially superposed with one another.

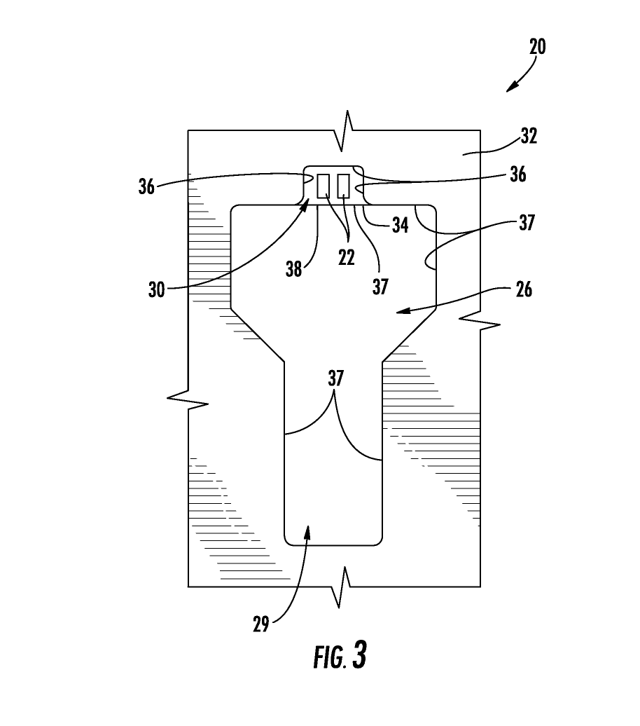

Referring also to FIG. 3, the inner peripheral edges of the upper and lower portions 32, 34 extend around and define the compound hole 29, and several of the inner peripheral edges of the upper portion 32 at least partially define the cavity 30. The inner peripheral edges of the upper portion that define the cavity 30 may be referred to as recessed peripheral edges 36, and the other inner peripheral edges may be referred to as nonrecessed peripheral edges 37.

The recessed peripheral edges 36 of the upper portion 32 may be recessed with respect to one or more of the nonrecessed peripheral edges 37, so that a protruding portion 38 of the lower portion 34 extends across and past the recessed peripheral edges 36. The protruding portion 38 of reduced thickness typically protrudes inwardly with respect to the through-hole 26. Alternatively, there may be only one of the recessed peripheral edges 36 that the protruding portion 38 extends across, such that the protruding portion may more generally extend across one or more (e.g., at least one) of the peripheral edges (e.g., the nonrecessed peripheral edges 37) of the upper portion 32. In the embodiment illustrated in the drawings, the recessed peripheral edges 36 may be substantially superposed with one another, and the nonrecessed peripheral edges 37 may be substantially superposed with one another.

For each unit 28, its non-conductive substrate may have numerous conductive traces, pads and/or other features mounted thereto, such as on one or both of its upper and lower sides, as discussed above. For example, in the embodiment illustrated in the drawings, the lower portion 34 of the circuit board includes upper conductors 22 (FIGS. 2-4) mounted on the upper surface of the uppermost nonconductive substrate of the lower portion, and lower conductors 24 (FIG. 5) mounted on the lower surface of the lowermost nonconductive substrate of the lower portion. In the embodiment shown in the drawings, at least a portion of each of the upper conductors 22 is located at the upper surface of the protruding portion 38, and these two portions of the upper conductors may be referred to as contact areas. Similarly, at least a portion of each of the lower conductors 24 is located at the lower surface of the protruding portion 38, and these two portions of the lower conductors may be referred to as contact areas. In the embodiment shown in the drawings, the contact areas of the upper conductors 22 are respectively superposed with the contact areas of the lower conductors 24. The contact areas of the conductors 22, 24 may be adjacent, proximate and/or recessed from one or more of the nonrecessed peripheral edges 37 of the lower portion 34.

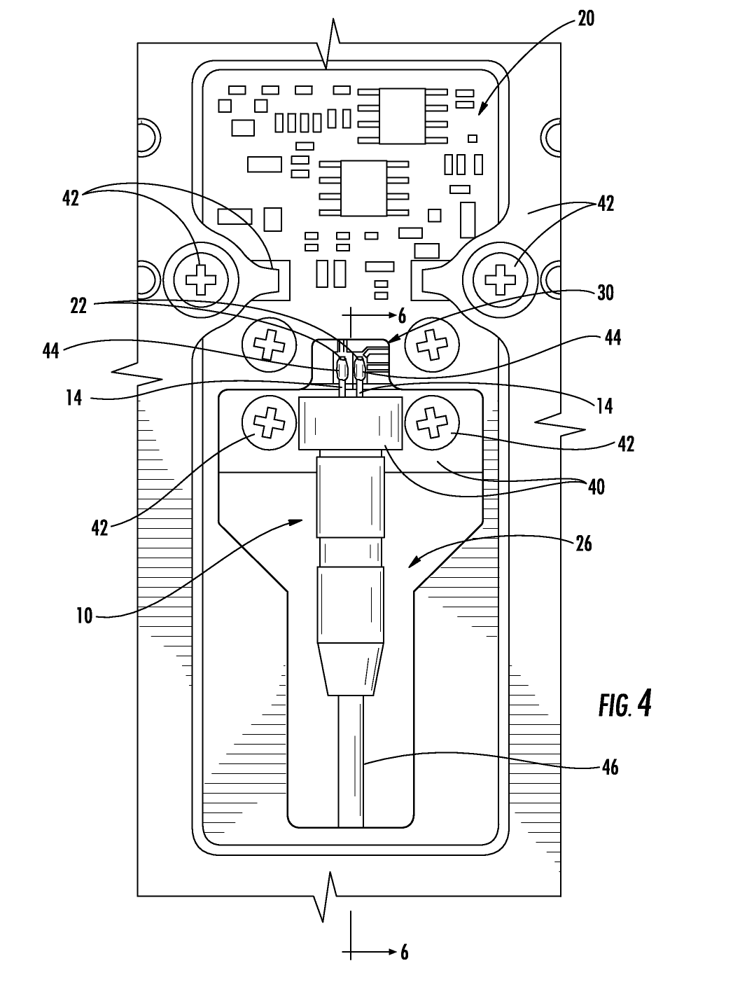

As best understood with reference to FIGS. 4 and 5, the laser 10 is mounted to the circuit board 20, such as through the use of one or more mounting brackets 40, so that the laser is at least partially positioned in the through-hole 26, the upper legs 14 are positioned in the cavity 30, the upper legs are respectively engaged against or closely adjacent to the contact areas of the upper conductors 22, and the lower legs 16 are respectively engaged against or closely adjacent to the contact areas of the lower conductors 24. As shown in FIG. 4, a variety of other mounting features 42 may be associated with the laser 10 and/or the circuit board 20.

The legs 14, 16 may be respectively electrically connected to the contact areas of the conductors 22, 24 with globs or beads of solder 44. Features of the laser 10 and the circuit board 20 may be configured so that for each of the soldered legs 14, 16, substantially the entire length of the leg may extend substantially straight, and the leg may extend substantially perpendicular to the base 12, or more specifically the plane of the exterior surface of the base. For example and as may be best understood with reference to FIG. 6, the thickness T of the protruding portion 38 of the lower portion 34 of the circuit board 20 may be substantially equal to (e.g., slightly smaller than) the gap G (FIG. 1) between the upper and lower legs 14, 16 while the legs extend substantially straight and substantially perpendicular to the base 12, or more specifically the plane of the exterior surface of the base. In one example, the gap G may be about 0.9 mm, such that the thickness T is less than about 0.9 mm, such as the thickness T being about 0.75 mm. When the thickness T is about 0.75 mm, the lower portion 34 and protruding portion 38 may include any suitable number of layers or units 28, such as one to four of them, so long as the thicknesses of the layers or units of the protruding portion 28 adds up to about 0.75 mm. Alternatively, the gap G, thickness T, and number of layers or units 28 may vary.

As shown in FIG. 4, an end of the laser 10 may be coupled to an end of an optical fiber cable 46 for transmitting optical signals through the cable in response to electrical signals being supplied to the laser from the circuit board 20 by way of the legs 14, 16. Alternatively, the laser may be used in any other suitable application.

An example of a method of assembling the circuit board 20 is discussed below, in accordance with an embodiment of this disclosure. The individual layers or units 28 may originally be formed separately. For each of the one or more units 28 of each of the upper and lower portions 32, 34, cutouts may be formed therein, for respectively forming the inner peripheral edges 36, 37, compound hole 29, through-hole 26 and cavity 30. The units 28 may be arranged in a stack so that the outer peripheral edges of the units are substantially superposed and the inner peripheral edges 36, 37 of the units are arranged as discussed above to form the compound hole 29 through-hole 26 and cavity 30. The units 28 may be secured together in one or more conventional manners that may include laminating.

Through relative movement between the laser 10 and the circuit board 20 in a first direction, the laser may be positioned in the through-hole 26. Then, through relative movement between the laser 10 and the circuit board 20 in a second direction, the protruding portion 38 of the lower portion 34 of the circuit board becomes positioned in the gap G (FIG. 1) between the upper and lower legs 14, 16, so that the legs become positioned relative to the contact areas of the conductors 22, 24 as discussed above. The first and second directions may be substantially perpendicular to one another. By way of the movement in the second direction, the base 12 of the laser 10 is brought closely adjacent to the inner end of the protruding portion 38 of the circuit board 20. Then, the body of the laser 10 is typically mounted to the chassis board with the mounting bracket 40 and screws, or in any other suitable manner. Then, the legs 14, 16 may be respectively soldered to the contact areas of the conductors 22, 24. Advantageously, the above-discussed method may be carried out without requiring or otherwise including any stretching or bending of the legs 14, 16. Alternatively, if desired and depending upon the relative importance of a variety of factors to be balanced, it is within the scope of this disclosure for some stretching or bending of the legs 14, 16 to occur, if necessary.

Generally reiterating from above and as schematically shown in FIG. 6, the circuit board may include layers or units 28 stacked and bonded in a multilayer structure. The layers or units 28 provide room for “running area” for the conductive traces connecting between the components of the circuit board. In one embodiment of this disclosure and as best understood with reference to FIG. 6, the protruding portion 38 of the circuit board 20 includes a lesser number of layers or units 28 as compared to another, thicker portion of the circuit board, so that the legs 14, 16 of the laser 10 may be soldered to the circuit board typically with a reduced amount of, or elimination of, any bending of the legs. As one example, the protruding portion 38 may include four layers or units 28, whereas the remainder of the circuit board 20 may include ten layers or units, although other numbers of layers are within the scope of this disclosure. The circuit board 20 may include any suitable number of layers or units, such as ten to sixteen of them. For example, at a position distant from the protruding portion 38, the circuit board 20 may have ten layers or units and, thus, may have a thickness of about 110 mil. In contrast, the protruding portion 38 provides an area of reduced thickness (e.g., may have a maximum thickness of less than about 110 mil) for allowing the legs 14, 16 of the laser 10 to be soldered on opposite sides of the protruding portion. Other thicknesses are within the scope of this disclosure. Optionally, the soldering may be replaced by or supplemented with any other suitable connecting.

Variations are within the scope of this disclosure. For example, at least a portion of the through-hole 26 may be omitted, and the laser 10 may be mounted at an outer peripheral edge (e.g., side) of the circuit board 20. As another example, the laser 10 may be configured differently than discussed above. In addition, the laser 10 may be more generally referred to as a light-emitting diode, or even more generally as an electronic device. That is, it is within the scope of this disclosure for the laser 10 to be replaced with any other suitable electronic device(s). As other examples and at least partially reiterating from above, each of the upper and lower portions 32, 34 may comprise, consist of or consist essentially of one or more units 28, and each of the upper and lower portions may optionally be referred to as a unit.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred.

It will be apparent to those skilled in the art that various modifications and variations can be made without departing from the spirit or scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

What is claimed is:

1. A circuit board for use with an electronic device, the circuit board comprising:
a plurality of units secured in a stack arrangement, the plurality of units comprising first and second units, and each of the first and second units comprising a non-conductive substrate comprising opposite major sides that each include peripheral edges, and a conductor mounted to the substrate;
a protruding portion of the first unit extending across and past at least one of the peripheral edges of the substrate of the second unit; and
the protruding portion of the first unit comprising at least a portion of the conductor of the first unit, so that the conductor of the first unit is configured for being connected to a conductor of the electronic device.

2. The circuit board of claim 1, wherein:
at least a portion of the conductor of the first unit is positioned proximate at least one edge of the peripheral edges of the first unit; and
the at least one of the peripheral edges of the second unit is recessed from the at least one of the peripheral edges of the first unit.

3. The circuit board of claim 1, wherein:
the conductor of the first unit is a first conductor of the first unit;
the first unit further comprises a second conductor of the first unit; and
the protruding portion of the first unit further comprises at least a portion of the second conductor of the first unit, so that the second conductor of the first unit is configured for being connected to another conductor of the electronic device.

4. The circuit board of claim 3, wherein:
the substrate of the first unit is a first substrate;
the first conductor of the first unit is mounted to the first substrate;
the first unit further comprises a second substrate that is non-conductive; and
the second conductor of the first unit is mounted to the second substrate.

5. The circuit board of claim 3, in combination with the electronic device, wherein:
a gap is defined between the conductor of the electronic device and the another conductor of the electronic device;
at least a portion of the first conductor of the first unit is positioned in the gap;
the first conductor of the first unit is connected to the conductor of the electronic device;
at least a portion of the second conductor of the first unit is positioned in the gap; and
the second conductor of the first unit is connected to the another conductor of the electronic device.

6. The combination of claim 5, wherein:
the first conductor of the first unit being connected to the conductor of the electronic device is comprised of the first conductor of the first unit being soldered to the conductor of the electronic device; and
the second conductor of the first unit being connected to the another conductor of the electronic device is comprised of the second conductor of the first unit being soldered to the another conductor of the electronic device.

7. The circuit board of claim 1, further comprising a hole in the circuit board, wherein:
the at least one of the peripheral edges of the second unit extends along and at least partially defines the hole; and
the protruding portion of the first unit extends inwardly with respect to the hole.

8. The circuit board of claim 7, wherein the stack has opposite sides, and the hole extends through the stack, from one of the sides of the stack to the other of the sides of the stack.

9. The circuit board of claim 1, in combination with the electronic device, wherein the conductor of the electronic device is soldered to the conductor of the first unit.

10. The combination of claim 9, wherein:
the electronic device comprises a laser diode;
the conductor of the laser diode is a conductive leg of the laser diode;
the laser diode further comprises second, third and fourth legs that are each electrically conductive;
the conductor of the first unit is a first conductor of the first unit;
the first unit further comprises second, third and fourth conductors;
the protruding portion of the first unit further comprises at least a portion of each of the second, third and fourth conductors of the first unit; and
the second, third and fourth conductors of the first unit are respectively soldered to the second, third and fourth legs of the laser diode.

11. A circuit board assembly, comprising:
an electronic device comprising first and second conductors protruding from a body, wherein a gap is defined between the first and second conductors of the electronic device; and
a circuit board comprising a non-conductive substrate positioned between first and second conductors of the first unit, wherein
at least a portion of a peripheral edge of the non-conductive substrate is positioned in the gap,
at least a portion of the first conductor of the first unit is positioned in the gap and connected to the first conductor of the electronic device, and
at least a portion of the second conductor of the first unit is positioned in the gap and connected to the second conductor of the electronic device.

12. The circuit board assembly of claim 11, wherein:
the electronic device is a laser diode device;
the body of the laser diode device includes a base; and
for each conductor of the first and second conductors of the laser diode device, a portion of the conductor of the laser diode device extends from the base to an outer end of the conductor of the laser diode device, and the portion of the conductor of the laser diode device is in at least one configuration selected from the group consisting of:
the portion of the conductor of the laser diode device extending substantially perpendicularly relative to the base, and
the portion of the conductor of the laser diode device being substantially straight.

13. The circuit board assembly of claim 11, wherein:
the circuit board comprises a hole; and
the electronic device is a laser diode device positioned in the hole.

14. The circuit board assembly of claim 11, wherein:
the substrate is a first substrate;
the circuit board further comprises a second substrate;
the first conductor of the first unit is mounted to the first substrate; and
the second conductor of the first unit is mounted to the second substrate.

15. A method of assembling a circuit board, comprising:
arranging a plurality of units comprising at least first and second units in a stack arrangement, wherein
each of the first and second units comprises a conductor mounted to a non-conductive substrate comprising opposite major sides that each include peripheral edges,
the first unit includes a predetermined portion comprising at least a portion of the conductor of the first unit, and
the arranging comprises arranging the first and second units in a predetermined configuration with respect to one another so that the predetermined portion of the first unit extends across and past at least one edge of the peripheral edges of the second unit; and
securing the first and second units in the predetermined configuration.

16. The method of claim 15, further comprising mounting an electronic device to the stack arrangement, comprising connecting the conductor of the first unit to a conductor of the electronic device.

17. The method of claim 15, wherein:
the electronic device comprises a laser diode;
the conductor of the laser diode is a first leg of the laser diode;
the conductor of the first unit is a first conductor of the circuit board;
the connecting comprises soldering the first leg to the first conductor of the circuit board; and
the mounting further comprises:
soldering a second conductor of the circuit board to a second leg of the laser diode;
soldering a third conductor of the circuit board to a third leg of the laser diode; and
soldering a fourth conductor of the circuit board to a fourth leg of the laser diode.

18. A method of assembling a circuit board assembly, comprising:
causing relative movement between an electronic device and a circuit board, wherein
the electronic device comprises first and second conductors protruding from a body of the electronic device, and a gap is defined between the first and second conductors of the electronic device,
the circuit board comprises a non-conductive substrate positioned between first and second conductors of the circuit board, and
the causing the relative movement comprises:
positioning at least a portion of the non-conductive substrate in the gap;
positioning at least a portion of the first conductor of the circuit board in the gap; and
positioning at least a portion of the second conductor of the circuit board in the gap;
connecting the first conductor of the circuit board to the first conductor of the electronic device; and
connecting the second conductor of the circuit board to the second conductor of the electronic device.

19. The method of claim 18, wherein:
the electronic device is a laser diode device;
the first conductor of the laser diode device is a first leg;
the second conductor of the laser diode device is a second leg; and
the positioning at least the portion of the first conductor of the circuit board in the gap and the positioning at least the portion of the conductor of the circuit board in the gap occur substantially simultaneously.

20. The method of claim 18, wherein the causing the relative movement between the electronic device and the circuit board is comprised of:
moving the electronic device into a hole in the circuit board, and
then causing relative movement between the electronic device and the circuit board so that both at least the portion of the first conductor of the circuit board and at least the portion of the second conductor of the circuit board enter the gap between the first and second conductors of the electronic device.
